(19) United States
(12) Patent Application Publication
(10) Pub. No.: US 2024/0190125 A1
(43) Pub. Date: Jun. 13, 2024

(54) JIG AND SCREEN-PRINTING APPARATUS INCLUDING THE SAME

(71) Applicant: SAMSUNG DISPLAY CO., LTD., YONGIN-SI (KR)

(72) Inventors: WONBEOM LEE, Yongin-si (KR); JUNEHYOUNG PARK, Yongin-si (KR); JUNWOO YOU, Yongin-si (KR); SUK WON JUNG, Yongin-si (KR)

(21) Appl. No.: 18/502,207

(22) Filed: Nov. 6, 2023

(30) Foreign Application Priority Data
Dec. 8, 2022 (KR) 10-2022-0170946

(51) Int. Cl. B41F 15/34

(52) U.S. Cl. CPC B41F 15/34; B41P 2200/40

(57) ABSTRACT

A screen-printing apparatus includes a jig including an opening penetrating along a thickness direction. The jig further includes a first surface extending in a first direction and a second direction each crossing the thickness direction, a second surface extending along the thickness direction, and a third surface opposed to the first surface. The opening penetrates the first surface and the third surface and is surrounded by the second surface. A pressing member is accommodated in the opening. The opening includes a first opening adjacent to the first surface and having a diameter changing along the thickness direction, and a second opening adjacent to the third surface and having a diameter constant along the thickness direction.

### CROSS-REFERENCE TO RELATED APPLICATIONS

This U.S. non-provisional patent application claims priority under 35 U.S.C. § 119 of Korean Patent Application No. 10-2022-0170946, filed on Dec. 8, 2022, the entire contents of which are hereby incorporated by reference.

### BACKGROUND

### 1. Technical Field

One or more embodiments described herein relate to a jig and a screen-printing apparatus including the same.

### 2. Description of the Related Art

A variety of electronic devices have been developed to include a display device for displaying images. Examples include televisions, mobile phones, tablet computers, navigation systems, and game consoles. As electronic devices are designed to have higher performance and are made to be thinner, their display devices and electronic components are becoming larger in capacity and more highly integrated.

### SUMMARY

One or more embodiments described herein provide a jig capable of securing thickness uniformity of an applied resin and a screen-printing apparatus.

An embodiment of the inventive concept provides a screen-printing apparatus including a jig including an opening which penetrates along a thickness direction, the jig including a first surface extending in a first direction and a second direction each crossing the thickness direction, a second surface extending along the thickness direction, and a third surface opposed to the first surface, the opening penetrating the first surface and the third surface and being defined the second surface, and a pressing member accommodated in the opening, wherein the opening includes a first opening adjacent to the first surface, and having a diameter changing along the thickness direction, and a second opening adjacent to the third surface, and having a diameter constant along the thickness direction.

In an embodiment, the second surface may include a first portion providing the first opening, and a second portion providing the second opening, wherein the first portion may be inclined with respect to the second portion, and may include at least one curved surface.

In an embodiment, the pressing member comprises a pressing part of which at least a portion is accommodated in the opening and which has the second direction as a rotational axis, the pressing part being in close contact with or spaced apart from the first portion.

In an embodiment, the pressing part may have a cylindrical shape extending along the second direction.

In an embodiment, the pressing part and the curved surface may have shapes corresponding to each other.

In an embodiment, the second opening may have a thickness of more than 0 μm and equal to or less than about 200 μm.

In an embodiment, the screen-printing apparatus may further include a resin accommodated in the opening, wherein the resin may include a light-blocking material, a heat-dissipating material, and an impact-resistance reinforcing material, and may have a thickness corresponding to a thickness of the second opening.

In an embodiment, the first portion may include a plurality of first sub-portions facing each other in the first direction and spaced apart from each other, each of the plurality of first sub-portions including the curved surface, and a plurality of second sub-portions facing each other in the second direction, each of the plurality of second sub-portions spaced apart from each other, and respectively connecting the first sub-portions.

In an embodiment, the second sub-portions may respectively have inclination angles different from inclination angles of the first sub-portions along the thickness direction.

In an embodiment, the pressing part may include a first pressing surface and a second pressing surface accommodated in the opening, and opposed to each other in the first direction, wherein a spacing between the first pressing surface and the second pressing surface changes along the thickness direction.

In an embodiment, the opening and the pressing member are each provided in plurality.

In an embodiment of the inventive concept, a screen-printing apparatus includes a jig which includes a first surface extending in a first direction and a second direction crossing each other, a second surface extending along a thickness direction, and a third surface opposed to the first surface, the second surface extending along the thickness direction to define an opening penetrating the first surface and the third surface, and a pressing member which extends along the second direction, and which includes a plurality of supporting parts supported by the first surface, and a pressing part disposed between the supporting parts so that at least a portion thereof is accommodated in the opening, wherein the second surface includes a first portion defining a first opening having a diameter changing along the thickness direction, and facing the pressing part in the first direction and the second direction, and a second portion connected to the first portion, and defining a second opening having a diameter constant along the thickness direction.

In an embodiment, the screen-printing apparatus may further include a resin accommodated in the opening, wherein the resin may include a light-blocking material, a heat-dissipating material, and an impact-resistance reinforcing material, and may have a thickness corresponding to a thickness of the second opening.

In an embodiment, the second opening may have a thickness of more than 0 μm and equal to or less than about 200 μm.

In an embodiment, the pressing part may have a cylindrical shape extending along the second direction, and each of a plurality of sub-portions, of the first portion, facing each other in the first direction may be recessed toward the pressing part.

In an embodiment, the first portion may include a plurality of first sub-portions facing each other in the first direction and spaced apart from each other, each of the plurality of first sub-portions including a recessed shape, and a plurality of second sub-portions facing each other in the second direction and spaced apart from each other, the plurality of second sub-portions respectively connecting the plurality of first sub-portions.

In an embodiment, the second sub-portions may have inclination angles different from inclination angles of the first sub-portions along the thickness direction.

In an embodiment of the inventive concept, a jig includes a first surface extending in a first direction and a second direction crossing each other, a second surface extending along a thickness direction crossing the first direction and the second direction, and a third surface opposed to the first direction, wherein the second surface defines an opening penetrating the first surface and the third surface, and the opening includes a first opening adjacent to the first surface, and having a diameter changing along the thickness direction, and a second opening adjacent to the second surface, and having a diameter constant along the thickness direction.

In an embodiment, the second surface may include a plurality of first sub-portions facing each other in the first direction while and apart from each other, each of the plurality of first sub-portions including a recessed shape, and a plurality of second sub-portions facing each other in the second direction and spaced apart from each other, the plurality of second sub-portions respectively connecting the plurality of first sub-portions, and the first sub-portions and the second sub-portions may have inclination angles different from each other along the thickness direction.

In an embodiment, the second opening may have a thickness of more than 0 μm and equal to or less than about 200 μm.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a schematic diagram illustrating a part of a display device according to an embodiment of the inventive concept;

FIG. 2 is a perspective view of a jig according to an embodiment of the inventive concept;

FIG. 3A is a plan view of a jig according to an embodiment of the inventive concept, and FIGS. 3B and 3C are cross-sectional views of a jig according to an embodiment of the inventive concept;

FIG. 4 is a perspective view of a screen-printing apparatus according to an embodiment of the inventive concept;

FIGS. 5A to 5D are cross-sectional views of a screen-printing apparatus illustrating operations of a method for manufacturing a display device according to an embodiment of the inventive concept;

FIG. 6 is a cross-sectional view of a screen-printing apparatus according to an embodiment of the inventive concept; and

FIG. 7 is a plan view of a jig according to an embodiment of the inventive concept.

### DETAILED DESCRIPTION

In this specification, when a component (or region, layer, portion, etc.) is referred to as “on”, “connected”, or “coupled” to another component, it means that it is placed/connected/coupled directly on the other component or a third component can be disposed between them.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Hereinafter, embodiments of the inventive concept will be described with reference to the drawings.

FIG. 1 is a schematic diagram illustrating a state in which a cover panel according to an embodiment of the inventive concept is disposed on a display panel of a display device. The display device DD may generate images and sense external inputs.

The display device DD may include a display module DM and electronic components. The display module DM may include a display panel DP, an optical layer OL, a cover panel CVP, and a window WD. FIG. 1 illustrates the display panel DP, the optical layer OL, the cover panel CVP, and the window WD in a stack structure of the display module DM, but another embodiment of the display module DM may have a different structure.

The display panel DP may display an image in response to an electrical signal. The display panel DP according to an embodiment may be a light-emitting display panel, but is not specially limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc.

The optical layer OL may be disposed on a front surface DP_F of the display panel DP. In one embodiment, the optical layer OL may be directly formed on the front surface DP_F of the display panel DP, but an embodiment of the inventive concept is limited thereto, e.g., one or more intervening layers may be included between the optical layer OL and the front surface DP_F of the display panel DP. After being separately manufactured, the optical layer OL may be disposed on the front surface DP_F of the display panel DP. The drawing illustrates a case in which the optical layer OL is disposed on the display panel DP, but in other embodiments the optical layer OL may be omitted.

The cover panel CVP may be disposed on a rear surface DP_B of the display panel DP. The cover panel CVP may be directly formed on the rear surface DP_B of the display panel DP. For example, the cover panel CVP may be coupled to a component defining the rear surface DP_B of the display panel DP without a separate adhesive layer.

The electronic components disposed on the rear surface DP_B of the display panel DP (for example, an electronic module EM, a power supply module, an electronic optical module, and flexible circuit boards) may generate heat. The cover panel CVP may prevent the heat generated by the electronic components from being transferred to the display panel DP, thus preventing damage to the display panel DP.

Additionally, the cover panel CVP may shield or absorb electromagnetic waves generated from the electronic components disposed on the rear surface DP_B of the display panel DP. Thus, the cover panel CVP may prevent the electromagnetic waves from adversely affecting the display panel DP in the form of noise. In addition, the cover panel CVP may block light emitted from the rear surface DP_B of the display panel DP, thereby preventing the electronic components disposed on the rear surface DP_B of the display panel DP from being viewed or reflected to the outside. In addition, the cover panel CVP may protect the display panel DP from external factors such as heat, impact, or electromagnetic waves transferred to the display panel DP, thereby improving reliability of the display panel DP and a display device.

The cover panel CVP may have a single-layered structure. In the case where the cover panel CVP has a single-layered structure and is directly formed on the rear surface DP_B of the display panel DP, the display device DD and the host electronic device (in which the display panel DP is disposed) may achieve reduced thickness, and reliability of the display panel DP may be improved as well. At this time, the cover panel CVP having the single-layered structure may not only dissipate heat but also protect the display panel DP from an external impact or interference transferred toward the rear surface DP_B of the display panel DP. For example, the cover panel CVP may function not only to dissipate heat but also to absorb impact and block light, electromagnetic waves, etc.

The cover panel CVP may be formed to have a single-layered structure through a UV curing method or a thermal curing method. However, the cover panel CVP may be formed through another curing method without being limited to the above-described methods, and the method for forming the cover panel is not limited to any one embodiment.

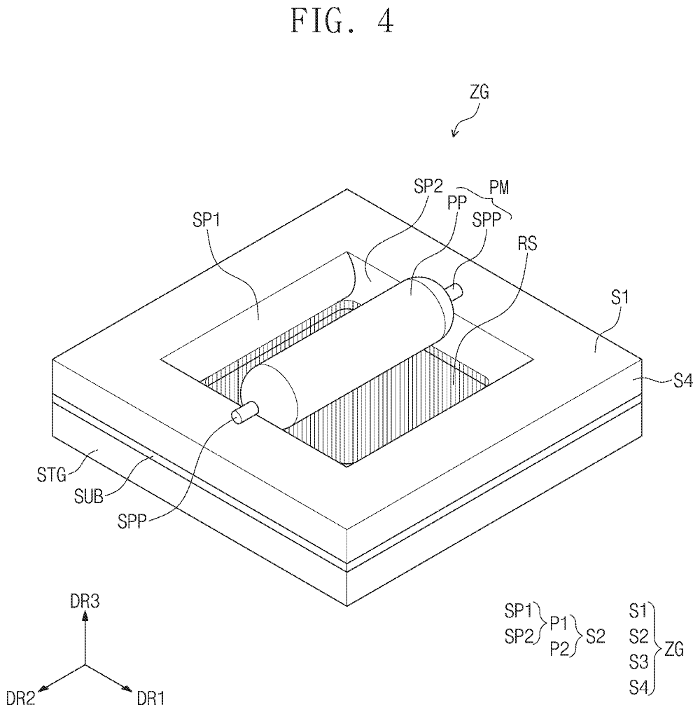

The cover panel CVP may be or include a resin RS (e.g., see FIG. 4) having a single-layered structure, as described above. However, the cover panel CVP is not limited to the single-layered structure, but in other embodiments may be provided to have a multi-layered structure. When the cover panel CVP has a multi-layered structure, the thickness of the multi-layered structure may have a thickness that conforms to the thickness Td of a second opening OP2 of a jig ZG, as described in greater detail below. Also, when the cover panel has a multi-layered structure, each layer may be made of the same materials (e.g., resin) or different materials.

The window WD may be disposed on the optical layer OL. The window WD may cover the front surface DP_F of the display panel DP, and may protect the display module DM from an external impact or a scratch. The window WD may be bonded to the optical layer OL, for example, through an adhesive layer.

The window WD may have a single- or multi-layered structure. For example, the window WD may include a plurality of plastic films bonded with an adhesive, or a glass film and a plastic film bonded with an adhesive. The window WD may further include a functional layer such as an anti-fingerprint layer, a phase control layer, and/or a hard-coating layer disposed on a transparent film.

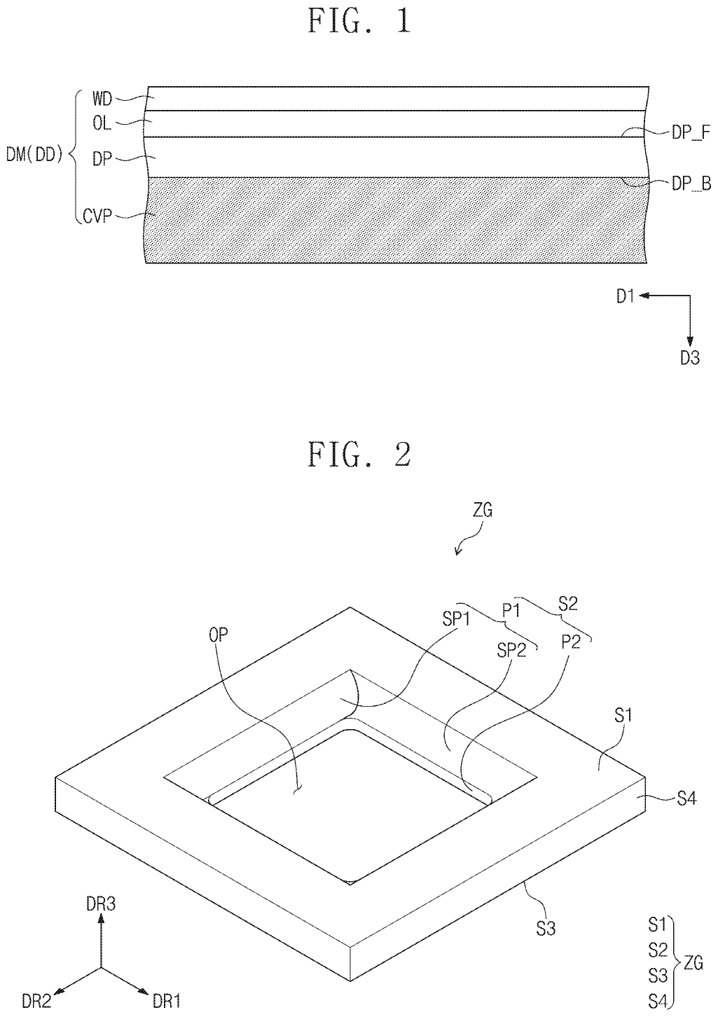

FIG. 2 is a perspective view of a jig ZG according to an embodiment of the inventive concept. The jig ZG according to an embodiment of the inventive concept may include a first surface S1, a second surface S2, a third surface S3, and a fourth surface S4.

The first surface S1 may correspond to an upper surface of the jig ZG. The first surface S1 may be a two-dimensional surface extending in a first direction DR1 and a second direction DR2. The second surface S2 may correspond to an inner surface of the jig ZG.

The second surface S2 may extend in a thickness direction of the jig ZG to be connected to the third surface S3. For example, the second surface S2 may extend in a third direction DR3 crossing each of the first direction DR1 and the second direction DR2 to be connected to the third surface S3. The second surface S2 may have a structure that provides an opening OP of the jig ZG. The thickness direction of the jig ZG may be parallel to the third direction DR3.

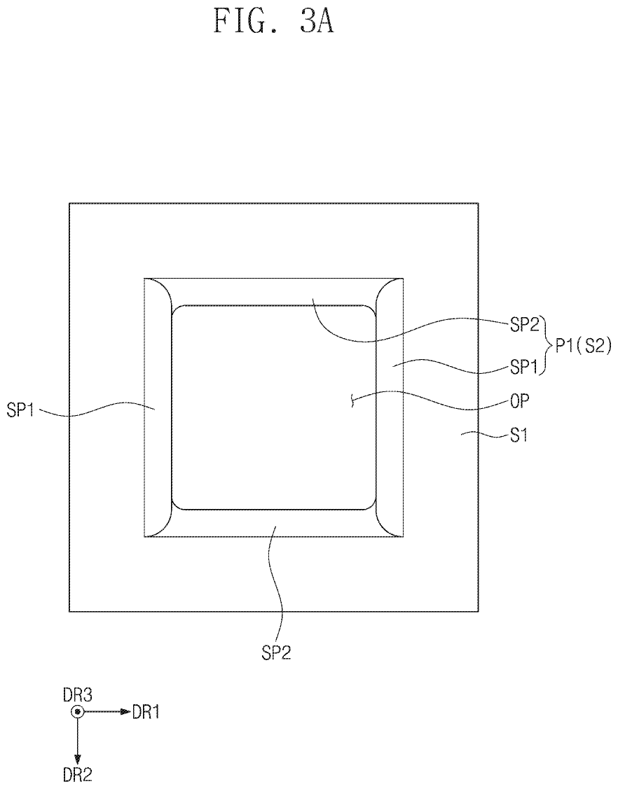

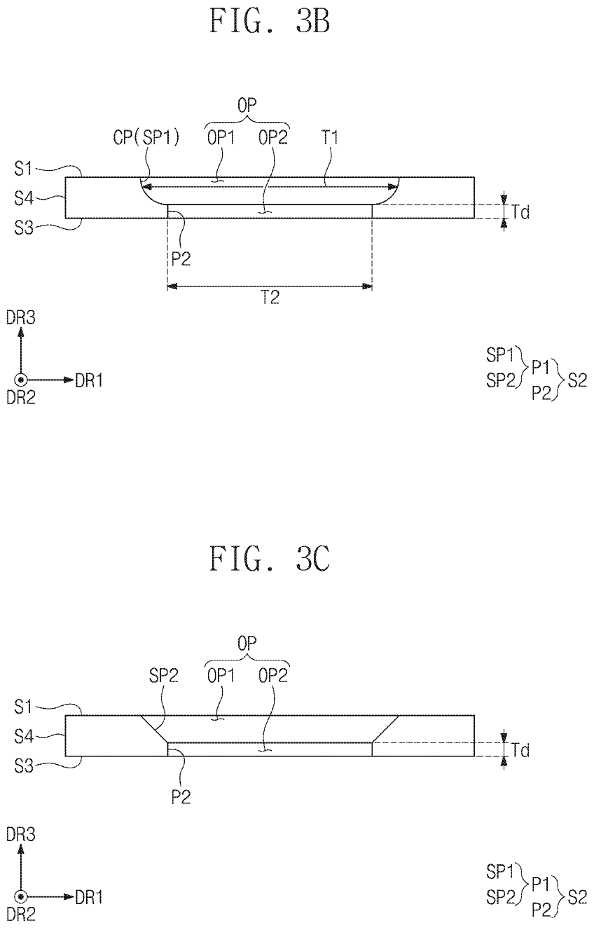

The third surface S3 may correspond to a lower surface of the jig ZG. The third surface S3 may be opposed to the first surface S1. FIGS. 3A to 3C show examples of the third surface S3.

The fourth surface S4 may correspond to an outer surface of the jig ZG. The fourth surface S4 may extend from the first surface S1 in the thickness direction to be connected to the third surface S3.

The opening OP may penetrate the first surface S1 and the third surface S3, and may be defined by the second surface S2. The opening OP may include one portion having a diameter changing along the thickness direction, and another portion having a diameter constant along the thickness direction. Embodiments thereof will be described in detail below.

The second surface S2 may include a first portion P1 and a second portion P2. The first portion P1 may be adjacent to the first surface S1, and the second portion P2 may be adjacent to the third surface S3. For example, the first portion P1 may be placed between the first surface S1 and the second portion P2, and the second portion P2 may be placed between the first portion P1 and the third surface S3.

The first portion P1 may be inclined with respect to the second portion P2. For example, the second portion P2 may extend in the thickness direction in a state of not being inclined (e.g., have vertical sidewalls), and the first portion P1 may be inclined with respect to the second portion P2. For example, the first portion P1 may be inclined by including at least one curved surface.

The first portion P1 may include a plurality of first sub-portions SP1 and a plurality of second sub-portions SP2. The plurality of first sub-portions SP1 may face each other and be spaced apart from each other in the first direction DR1, and the plurality of second sub-portions SP2 may face each and be being spaced apart from each other in the second direction DR2.

The plurality of first sub-portions SP1 may be inclined with respect to the second portion P2, and the plurality of second sub-portions SP2 may be inclined with respect to the second portion P2. For example, the first sub-portions SP1 and/or the second sub-portions SP2 of the first portion P1 may each include a curved surface.

According to an embodiment of the inventive concept, the first sub-portion SP1 and the second sub-portion SP2 may have inclination angles different from each other. For example, inclination slopes of the first sub-portion SP1 and the second sub-portion SP2 may be different from each other, but an embodiment of the inventive concept is not limited thereto. In one embodiment, the inclination slopes of the first sub-portions SP1 and the second sub-portions SP2 may be the same, and are not limited to any one embodiment.

The first sub-portion SP1 and/or the second sub-portion SP2 may each include a curved surface. For example, the first sub-portion SP1 and/or the second sub-portion SP2 may have a shape partially recessed toward a fourth surface S4. FIG. 2 illustrates a case in which the entire first sub-portion SP1 has a curved surface, but an embodiment of the inventive concept is not limited thereto. The first sub-portion SP1 may have a partially curved surface in one embodiment.

FIG. 3A is a plan view of the jig ZG according to an embodiment of the inventive concept, and FIGS. 3B and 3C are cross-sectional views of the jig ZG according to an embodiment of the inventive concept.

FIGS. 3A to 3C illustrate that the entire first sub-portion SP1 has a curved surface, but an embodiment of the inventive concept is not limited thereto. The first sub-portion SP1 may have a partially curved surface, and is not limited to any one embodiment. In addition, it is illustrated that the entire second sub-portion SP2 is inclined, but an embodiment of the inventive concept is not limited thereto. The second sub-portion SP2 may be partially inclined in another embodiment.

Referring to FIG. 3A, the first portion P1 may include a plurality of first sub-portions SP1 spaced apart from each other with an opening OP therebetween, and a plurality of second sub-portions SP2 spaced apart from each other with the opening OP therebetween. For example, the plurality of first sub-portions SP1 may face each other while being spaced apart in the first direction DR1, and the plurality of second sub-portions SP2 may face each other while being spaced in the second direction DR2. The plurality of second sub-portions SP2 may respectively connect the first sub-portions SP1 spaced apart from each other.

Referring to FIG. 3B, the opening OP may include a first opening OP1 and a second opening OP2. The first opening OP1 may be adjacent to the first surface S1, and may have a varying diameter, e.g., a diameter changing along the thickness direction. The second opening OP2 may be adjacent to the third surface S3, and may have a diameter that is constant along the thickness direction. Referring to FIG. 3B, a first diameter T1 of the first opening OP1 may change along the thickness direction (which is the third direction DR3), but a second diameter T2 of the second opening OP2 may be fixed or constant along the third direction DR3.

In one embodiment, the thickness Td of the second opening OP2 may be more than 0 μm and equal to or less than about 200 μm, and for example, may be about 200 μm. Since the second opening OP2 is provided to have a thickness Td of more than 0 μm and equal to or less than about 200 μm, a thin film may be formed using a resin RS (e.g., see FIG. 4) on the substrate SUB. The thickness of the second opening OP2, and thus, the thickness Td of the resin, may lie in a different range (e.g., greater than 200 μm) in another embodiment.

The first portion P1 may determine the size of first opening OP1 described above, and the second portion P2 may determine the size of the second opening OP2 described above. For example, the first portion P1 may have a thickness corresponding to the first opening OP1, and the second portion P2 may have the thickness Td corresponding to the second opening OP2. The thickness of the first portion P1 may be greater than the thickness Td of the second portion P2.

By increasing the thickness of the first portion P1, the rigidity of the entire jig ZG may be increased. This may make it possible to prevent lowering of quality that may be caused by misalignment of the resin RS on the substrate SUB during a printing process to be described later. In addition, by increasing the thickness of the first portion P1 and increasing the size of a pressing member PM (e.g., see FIG. 4) accommodated in the first portion P1, the pressing member PM may more strongly pressurize the resin RS accommodated in the opening OP. Also, the number of times the pressing member PM is moved may be reduced. As a result, costs may be reduced and mass productivity may be increased.

Referring to FIGS. 3B and 3C, according to an embodiment of the inventive concept, the first sub-portion SP1 and the second sub-portion SP2 may have inclination angles different from each other. For example, the inclination angles of the first sub-portion SP1 and the second sub-portion SP2 may be different from each other, but an embodiment of the inventive concept is not limited thereto. For example, a part of the first sub-portion SP1 and a part of the second sub-portion SP2 may have the same inclination slope, and are not limited to any one embodiment. When the first sub-portion SP1 and the second sub-portion SP2 have different inclination angles, pressing members having various sizes may be used.

In one embodiment, the first sub-portions SP1 and/or the second sub-portions SP2 may each include a curved surface. For example, the first sub-portions SP1 and/or the second sub-portions SP2 may each have a shape partially recessed toward the fourth surface S4. FIG. 3B illustrates that the entire first sub-portion SP1 has a curved surface CP. However, an embodiment of the inventive concept is not limited thereto, and only a portion of the first sub-portion SP1 may have a curved surface CP in other embodiments. In one embodiment, the first sub-portion SP1 and also the second sub-portion SP2 may include a curved surface CP, and are not limited to any one embodiment.

FIG. 4 is a perspective view of a screen-printing apparatus according to an embodiment of the inventive concept.

Referring to FIG. 4, a stage STG may support a substrate SUB and jig ZG and may extend in the first direction DR1 and the second direction DR2. The substrate SUB may be disposed between the jig ZG and the stage STG. The substrate SUB may be the display panel DP (e.g., see FIG. 1) described above. However, an embodiment of the inventive concept is not limited thereto, and the substrate SUB may be a part of the display module DM (e.g., see FIG. 1) described above.

The screen-printing apparatus according to an embodiment of the inventive concept may include the jig ZG and a pressing member PM. The jig ZG and the pressing member PM may have low adhesion with a resin RS. For example, since a coating layer having low adhesion relative to the resin RS is formed on surfaces of the jig ZG and the pressing member PM, the jig ZG and the pressing member PM may be easily separated from the resin RS. The jig ZG may be disposed on the stage STG and may be the same as the jig ZG described in FIGS. 2 and 3A to 3C.

The pressing member PM may include a plurality of supporting parts SPP and a pressing part PP. The plurality of supporting parts SPP extend along the second direction DR2 and are supported by the first surface S1. The plurality of supporting parts SPP may be supported by the first surface S1, and may move along the first direction DR1.

The pressing part PP may be disposed between the plurality of supporting parts SPP so that at least a part thereof may be accommodated in the opening OP. For example, the pressing part PP may extend in the second direction DR2 to be connected to the supporting parts SPP. The pressing part PP may be formed integrally with the supporting part SPP, but an embodiment of the inventive concept is not limited thereto. The pressing part PP may be separably formed in other embodiments.

The pressing part PP may rotationally move in the first direction DR1 with the second direction DR2 as a rotation axis. While rotationally moving in the first direction DR1, the pressing part PP may be in close contact with or spaced apart from the first portion P1. The pressing part PP (e.g., a roller) may have a predetermined (e.g., cylindrical) shape extending along the second direction DR2. For example, the pressing part PP may have a cylindrical shape formed by extending along a rotation axis direction.

A curved surface of the first sub-portion SP1 of the jig ZG may have a shape partially recessed toward the fourth surface S4. According to an embodiment of the inventive concept, the curved surface of the first sub-portion SP1 of the jig ZG and an outer surface of the pressing part PP may correspond to (e.g., be complementary with) each other. For example, the curved surface of the first sub-portion SP1 of the jig ZG and the outer surface of the pressing part PP may substantially have the same curvature. When the pressing part PP moves in the first direction DR1, the curved surface of the first sub-portion SP1 of the jig ZG and the outer surface of the pressing part PP may be in close contact with each other.

The resin RS may be accommodated in the opening OP. The resin RS may be accommodated in the opening OP and disposed on the substrate SUB. The resin RS may form a single-layered structure on the substrate SUB, but may have a multi-layered structure in another embodiment. The resin RS may include fluid having high viscosity. Since the resin RS has a good adhesion with the substrate SUB, the resin RS may be in close contact with the substrate SUB. However, the resin RS may have a low adhesion with the jig ZG and the pressing member PM. Accordingly, the jig ZG and the pressing member PM may be easily separated from the resin RS.

The resin RS may include a light-blocking material, a heat-dissipating material, and an impact-resistance reinforcing material. Since the resin RS including all of the light-blocking material, the heat-dissipating material, and the impact-resistance reinforcing material is used to form a single-layered structure, a thin display device DD (e.g., see FIG. 1) may be manufactured. For example, the resin RS may include a light-blocking material having a black color, an impact-resistance reinforcing material for reinforcing an impact-resistance of a display panel or a display module, and a heat dissipating material for preventing heat generated in a host electronic module, etc., from being transferred to the display panel or the display module DM (e.g., see FIG. 1). In one embodiment, the resin RS may include at least one of the light-blocking material, the heat-dissipating material, or the impact-resistance reinforcing material that forms a single- or multi-layered structure.

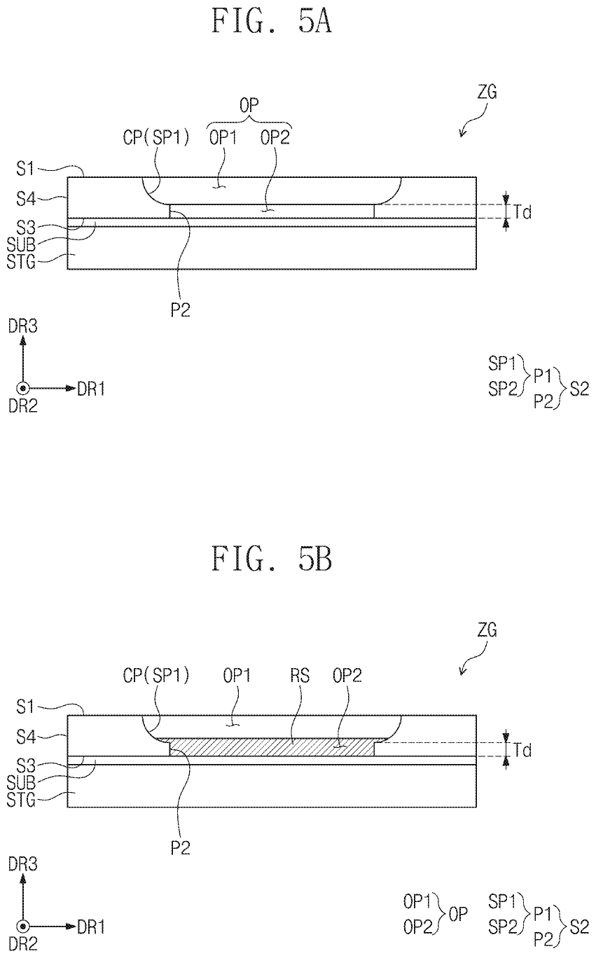

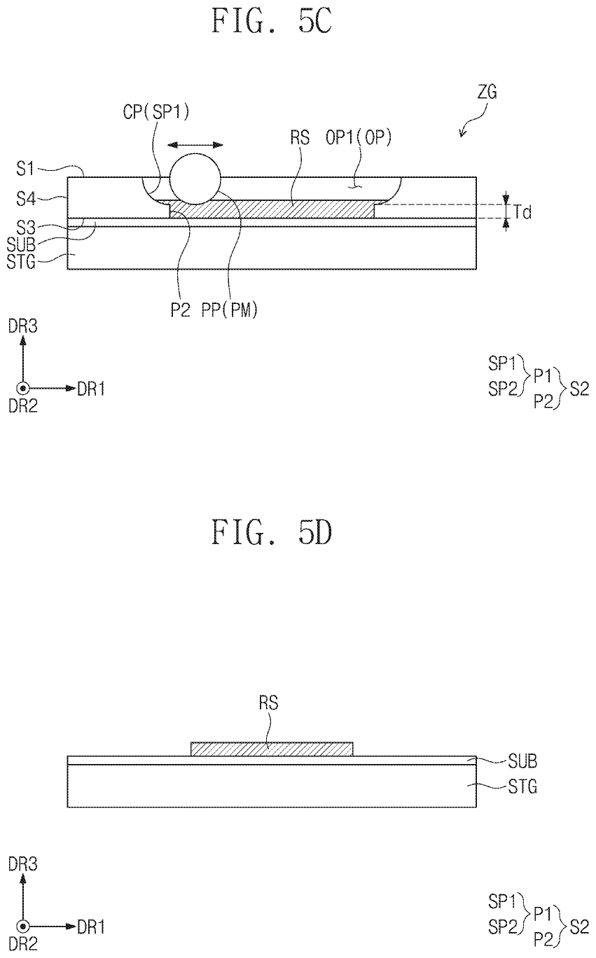

FIGS. 5A to 5D are cross-sectional views of a screen-printing apparatus used to perform operations of a method for manufacturing a display device according to an embodiment of the inventive concept.

The method for manufacturing a display device according to an embodiment of the inventive concept may include disposing a substrate SUB and a jig ZG on a stage STG, injecting a resin RS (e.g., as previously described) into an opening OP of the jig ZG, pressing the resin RS injected into the opening OP, and removing the jig ZG. According to an embodiment of the inventive concept, process operations may be simplified, so that costs may be reduced and mass productivity may be increased in manufacture of a cover panel CVP (e.g., see FIG. 1). While the method for manufacturing a display device according to an embodiment of the inventive concept may be applied to the manufacture of the cover panel CVP (see FIG. 1), in one embodiment the method may be also applied to manufacture of other components of the display device or host electronic device.

In the method for manufacturing a display device according to an embodiment of the inventive concept, additionally processing the resin RS pressed by the pressing member PM is not illustrated, but additionally processing the pressed resin RS may be further performed, and an embodiment of the inventive concept is not limited thereto.

FIG. 5A illustrates disposing a substrate SUB and a jig ZG on a stage STG, FIG. 5B illustrates injection a resin RS into an opening OP of the jig ZG, FIG. 5C illustrates of pressing the resin RS injected into the opening OP, and FIG. 5D illustrates removing part of the resin RS and the jig ZG together.

Referring to FIG. 5A, the substrate SUB and the jig ZG may be sequentially disposed on the stage STG. The jig ZG may be supported by a supportable object to prevent the jig ZG from excessively pressing the substrate SUB in a gravitational force direction.

Referring to FIG. 5B, the resin RS may be injected into the opening OP of the jig ZG. FIG. 5B illustrates that the resin RS is injected into a part of the first opening OP1 and the second opening OP2, but an embodiment of the inventive concept is not limited to what is illustrated in the drawing. In one embodiment, the resin RS may be injected only into the second opening OP2.

Referring to FIG. 5C, the pressing member PM may be positioned in the opening OP and rotationally moved along the first direction DR1 to allow the resin RS to be pressed by the pressing member PM. While the pressing member PM presses the resin RS, a degree of adhesion between the resin RS and the substrate SUB may be increased, and the surface uniformity of the resin RS may be also increased.

In addition, the pressing member PM presses the resin RS so that the resin RS previously accommodated in the first opening OP1 and the second opening OP2 may now be accommodated only in the second opening OP2, or at least is included to a reduced degree in the first opening OP1. For example, in one embodiment, the pressing operation may be performed so that the thickness of the resin RS accommodated and pressed in the opening OP may correspond to a thickness of the second opening OP2. This may be accomplished by controlling the amount of resin injected into the opening OP. For example, the thickness of the pressed resin RS may be more than 0 μm and equal to or less than about 200 μm. Using the resin RS having a small thickness makes it possible to achieve high integration and miniaturization of the display module DM (e.g., see FIG. 1), the display device DD (e.g., see FIG. 1), and an electronic device. The pressed resin RS may have a thickness different from (e.g., greater than) 200 μm in another embodiment.

The curved surface CP of the first sub-portion SP1 of the jig ZG may have a shape recessed toward the pressing part PP. In addition, the curved surface CP of the first sub-portion SP1 of the jig ZG and the outer surface of the pressing part PP may correspond to each other, e.g., may be complementary surfaces so that they at least substantially fit together. When the pressing member PM moves along the first direction DR1, the curved surface CP of the first sub-portion SP1 of the jig ZG and the outer surface of the pressing part PP may therefore be in close contact with each other. In one embodiment, the curved surface CP of the first sub-portion SP1 and the outer surface of the pressing part PP may correspond to each other, so that the pressing member PM may be prevented from moving inside the opening OP in the third direction DR3. This makes it possible for the pressing member PM to uniformly press the resin RS at the center or edge side of the opening OP. Therefore, the surface uniformity of the resin RS may be increased.

Referring to FIGS. 5C and 5D, the jig ZG may be removed from the substrate SUB. In the event that a portion of the resin RS overlaps the first portion P1 after pressing, not only the resin RS overlapping the second portion P2 of the jig ZG, but also the resin RS overlapping the first portion P1 of the jig ZG may be removed together. The resin RS overlapping the first portion P1 may be prevented from falling on the surface of the resin RS overlapping the second portion P2, thereby increasing the surface uniformity of the resin RS remaining on the substrate SUB.

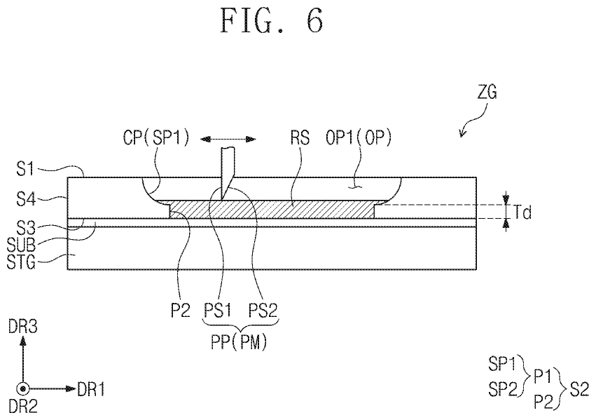

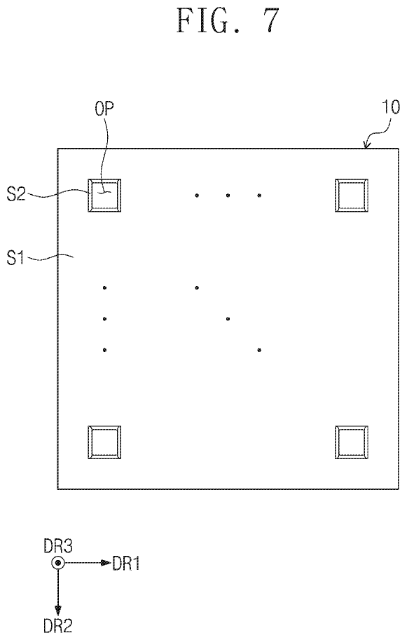

FIG. 6 is a cross-sectional view of a screen-printing apparatus according to an embodiment of the inventive concept.

Referring to FIG. 6, according to an embodiment of the inventive concept, the pressing member PM may be accommodated in the opening OP, and may include a first pressing surface PS1 and a second pressing surface PS2 opposed to each other in the first direction DR1.

The second pressing surface PS2 may be disposed at a predetermined angle (e.g., an acute angle) relative to the first pressing surface PS1. As a result, the distance between the first pressing surface PS1 and the second pressing surface PS2 may vary along a thickness direction. For example, the distance between the first pressing surface PS1 and the second pressing surface PS2 may become larger along the third direction DR3, and may become smaller along an opposite direction of the third direction DR3. A point where the first pressing surface PS1 and the second pressing surface PS2 intersect may contact and thus apply pressure (or scrape) the resin accommodated in the jig.

In one embodiment, the resin RS accommodated in the first opening OP1 of the resin RS accommodated in the opening OP may be pressed to the first pressing surface PS1 or the second pressing surface PS2 of the pressing member PM, so that a thickness of the resin RS accommodated in the second opening OP2 may be substantially the same as a thickness of the second opening OP2.

FIG. 7 is a plan view of a jig ZG according to an embodiment of the inventive concept.

Referring to FIG. 7, the jig ZG according to an embodiment of the inventive concept may include a plurality of openings OP. The plurality of openings OP may be disposed spaced apart from each other along the first direction DR1 or the second direction DR2. A plurality of pressing members PM may be also provided to correspond to the number of the openings OP, and the resin RS may be supplied to each of the openings OP. Process operations as described above may be also performed in a case where the jig ZG includes the plurality of openings OP.

A jig and a screen-printing apparatus according to an embodiment of the inventive concept may secure the surface uniformity of a resin being applied. The resin RS may include a light-blocking material, a heat-dissipating material, and/or an impact-resistance reinforcing material. In some embodiments, the resin RS has all three properties and may have a single-layered or multi-layered structure. As a result, a display device DD may be manufactured that has a reduced thickness compared to other proposed display devices. In some embodiments, the resin RS may include a light-blocking material having a black color, an impact-resistance reinforcing material for reinforcing an impact-resistance of a display panel or a display module, and a heat dissipating material for preventing heat generated in a host electronic module, etc., from being transferred to the display panel or the display module DM (e.g., see FIG. 1).

In the above, description has been made with reference to preferred embodiments of the inventive concept, but those skilled in the art or those of ordinary skill in the relevant technical field may understand that various modifications and changes may be made to the inventive concept within the scope not departing from the spirit and the technology scope of the inventive concept described in the claims to be described later. Therefore, the technical scope of the inventive concept is not limited to the contents described in the detailed description of the specification, but should be determined by the claims. The embodiments may be combined to form additional embodiments.

What is claimed is:

1. A screen-printing apparatus comprising:
a jig including an opening which penetrates along a thickness direction, the jig including a first surface extending in a first direction and a second direction each crossing the thickness direction, a second surface extending along the thickness direction, and a third surface opposed to the first surface, the opening penetrating the first surface and the third surface and being defined by the second surface; and
a pressing member accommodated in the opening, wherein the opening includes:
a first opening adjacent to the first surface and having a diameter changing along the thickness direction, and
a second opening adjacent to the third surface and having a diameter which is constant along the thickness direction.

2. The screen-printing apparatus of claim 1, wherein the second surface comprises:
a first portion defining the first opening; and
a second portion defining the second opening, and
wherein the first portion is inclined with respect to the second portion and includes at least one curved surface.

3. The screen-printing apparatus of claim 2, wherein:
the pressing member comprises a pressing part of which at least a portion is accommodated in the opening and which has the second direction as a rotational axis, the pressing part being in close contact with or spaced apart from the first portion.

4. The screen-printing apparatus of claim 3, wherein the pressing part has a cylindrical shape extending along the second direction.

5. The screen-printing apparatus of claim 3, wherein the pressing part and the curved surface have shapes corresponding to each other.

6. The screen-printing apparatus of claim 2, wherein the second opening has a thickness of more than 0 μm and equal to or less than about 200 μm.

7. The screen-printing apparatus of claim 2, further comprising:
a resin accommodated in the opening,
wherein the resin includes a light-blocking material, a heat-dissipating material, and an impact-resistance reinforcing material, and has a thickness corresponding to a thickness of the second opening.

8. The screen-printing apparatus of claim 2, wherein the first portion comprises:
a plurality of first sub-portions facing each other in the first direction and spaced apart from each other, each of the plurality of first sub-portions including a curved surface; and
a plurality of second sub-portions facing each other in the second direction and spaced apart from each other, the plurality of second sub-portions respectively connecting the plurality of first sub-portions.

9. The screen-printing apparatus of claim 8, wherein the plurality of second sub-portions respectively have inclination angles different from inclination angles of the first sub-portions along the thickness direction.

10. The screen-printing apparatus of claim 2, wherein the pressing part comprises:
a first pressing surface and a second pressing surface accommodated in the opening and opposed to each other in the first direction, wherein a spacing between the first pressing surface and the second pressing surface changes along the thickness direction.

11. The screen-printing apparatus of claim 1, wherein the opening and the pressing member are each provided in plurality.

12. A screen-printing apparatus comprising:
a jig which includes a first surface extending in a first direction and a second direction crossing each other, a second surface extending along a thickness direction, and a third surface opposed to the first surface, the second surface extending along the thickness direction to define an opening penetrating the first surface and the third surface; and
a pressing member which extends along the second direction and which includes a plurality of supporting parts supported by the first surface and a pressing part disposed between the supporting parts, at least a portion of the pressing part accommodated in the opening,
wherein the second surface includes:
a first portion defining a first opening having a diameter changing along the thickness direction, and facing the pressing part in the first direction and the second direction, and
a second portion connected to the first portion and defining a second opening having a diameter constant along the thickness direction.

13. The screen-printing apparatus of claim 12, further comprising:
a resin accommodated in the opening,
wherein the resin includes a light-blocking material, a heat-dissipating material, and an impact-resistance reinforcing material, and has a thickness corresponding to a thickness of the second opening.

14. The screen-printing apparatus of claim 12, wherein the second opening has a thickness of more than 0 μm and equal to or less than about 200 μm.

15. The screen-printing apparatus of claim 12, wherein:
the pressing part has a cylindrical shape extending along the second direction, and
each of a plurality of sub-portions, of the first portion, facing each other in the first direction is recessed toward the pressing part.

16. The screen-printing apparatus of claim 12, wherein the first portion comprises:
a plurality of first sub-portions facing each other in the first direction and spaced apart from each other, each of the plurality of sub-portions including a recessed shape; and
a plurality of second sub-portions facing each other in the second direction and spaced apart from each other, the plurality of second sub-portions respectively connecting the plurality of first sub-portions.

17. The screen-printing apparatus of claim 16, wherein the plurality of second sub-portions have inclination angles different from inclination angles of the plurality of first sub-portions along the thickness direction.

18. A jig comprising:
a first surface extending a first direction and a second direction crossing each other;
a second surface extending along a thickness direction crossing the first direction and the second direction; and
a third surface opposed to the first direction, wherein:
the second surface defines an opening penetrating the first surface and the third surface, and
the opening includes:
a first opening adjacent to the first surface, and having a diameter changing along the thickness direction, and
a second opening adjacent to the second surface, and having a diameter constant along the thickness direction.

19. The jig of claim 18, wherein the second surface comprises:
a plurality of first sub-portions facing each other in the first direction and spaced apart from each other, each of the plurality of first sub-portions including a recessed shape; and
a plurality of second sub-portions facing each other in the second direction and spaced apart from each other, the plurality of second sub-portions respectively connecting the plurality of first sub-portions, the plurality of first sub-portions and the plurality of second sub-portions having inclination angles different from each other along the thickness direction.

20. The jig of claim 18, wherein the second opening has a thickness of more than 0 μm and equal to or less than about 200 μm.
